(19) United States
(12) Patent Application Publication
(10) Pub. No.: US 2026/0090285 A1
(43) Pub. Date: Mar. 26, 2026

(54) LATTICE PLANE BASED VACUUM CAPACITOR FOR QUANTUM CHIPS

(71) Applicant: INTERNATIONAL BUSINESS MACHINES CORPORATION, ARMONK, NY (US)

(72) Inventors: SANTINO CARNEVALE, Stamford, CT (US); Conal Murray, Yorktown Heights, NY (US); Marco Turchetti, White Plains, NY (US)

(21) Appl. No.: 18/892,235

(22) Filed: Sep. 20, 2024

(51) Int. Cl. H10N 60/80; H10N 60/01; H10N 60/12

(52) U.S. Cl. CPC H10N 60/805; H10N 60/0912; H10N 60/12

(57) ABSTRACT

A structure that includes a first capacitor plate located on a first surface of a substrate and a second capacitor plate located on a second surface of the substrate. A top surface of the first capacitor plate is angled towards a top surface of the second capacitor plate.

### BACKGROUND

The present invention generally relates to the field of quantum chips, and more particularly to a design for a qubit.

Superconducting quantum computing systems can comprise one or more superconducting qubits. These qubits are generally formed by a nonlinear inductor (Josephson Junction) in parallel with shunting capacitors.

### BRIEF SUMMARY

Additional aspects and/or advantages will be set forth in part in the description which follows and, in part, will be apparent from the description, or may be learned by practice of the invention.

A structure that includes a first capacitor plate located on a first surface of a substrate and a second capacitor plate located on a second surface of the substrate. A top surface of the first capacitor plate is angled towards a top surface of the second capacitor plate.

A structure that includes a first capacitor plate located a first surface of a substrate and a second capacitor plate located on a second surface of the substrate. A top surface of the first capacitor plate is angled towards a top surface of the second capacitor plate. An air gap located beneath the first capacitor plate and the second capacitor plate.

A structure that includes a first capacitor plate located a first surface of a substrate. The first capacitor plate includes a first branch arm that extends along a flat surface of the substrate. A second capacitor plate located on a second surface of the substrate. The second capacitor plate includes a second branch arm that extends along the flat surface of the substrate. A top surface of the first capacitor plate is angled towards a top surface of the second capacitor plate. A Josephson Junction is located between the first branch arm and the second branch arm.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of the Qubit after an initial stage of processing, in accordance with the embodiment of the present invention.

FIG. 2 illustrates cross-section X of the Qubit after the initial stage of processing, in accordance with the embodiment of the present invention.

FIG. 3 illustrates a top-down view of the Qubit after formation and development of a lithography layer, in accordance with the embodiment of the present invention.

FIG. 4 illustrates cross-section X of the Qubit after formation and development of a lithography layer, in accordance with the embodiment of the present invention.

FIG. 5 illustrates a top-down view of the Qubit after formation of the first trench, in accordance with the embodiment of the present invention.

FIG. 6 illustrates cross-section X of the Qubit after formation of the first trench, in accordance with the embodiment of the present invention.

FIG. 7 illustrates a top-down view of the Qubit after removal of the lithography layer, in accordance with the embodiment of the present invention.

FIG. 8 illustrates cross-section X of the Qubit after removal of the lithography layer, in accordance with the embodiment of the present invention.

FIG. 9 illustrates a top-down view of the Qubit after formation of a metal layer, in accordance with the embodiment of the present invention.

FIG. 10 illustrates cross-section X of the Qubit after formation of a metal layer, in accordance with the embodiment of the present invention.

FIG. 11 illustrates a top-down view of the Qubit after formation and exposure of a second lithography layer, in accordance with the embodiment of the present invention.

FIG. 12 illustrates cross-section X of the Qubit after formation and exposure of a second lithography layer, in accordance with the embodiment of the present invention.

FIG. 13 illustrates a top-down view of the Qubit after removal of non-exposed portions of the second lithography layer, in accordance with the embodiment of the present invention.

FIG. 14 illustrates cross-section X of the Qubit after removal of non-exposed portions of the second lithography layer, in accordance with the embodiment of the present invention.

FIG. 15 illustrates a top-down view of the Qubit after etching of the metal layer, in accordance with the embodiment of the present invention.

FIG. 16 illustrates cross-section X of the Qubit after etching of the metal layer, in accordance with the embodiment of the present invention.

FIG. 17 illustrates a top-down view of the Qubit after removal of the first component and the second component, in accordance with the embodiment of the present invention.

FIG. 18 illustrates cross-section X of the Qubit after removal of the first component and the second component, in accordance with the embodiment of the present invention.

FIG. 19 illustrates a top-down view of the Qubit after formation of the air gap, in accordance with the embodiment of the present invention.

FIG. 20 illustrates cross-section X of the Qubit after formation of the air gap, in accordance with the embodiment of the present invention.

FIG. 21 illustrates a top-down view of the Qubit after formation of the Josephson Junction, in accordance with the embodiment of the present invention.

FIG. 22 illustrates cross-section X of the Qubit after formation of the Josephson Junction, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

Superconducting quantum computing systems can comprise one or more superconducting qubits. These qubits can be formed by a nonlinear inductor (Josephson Junction) in parallel with shunting capacitors. Josephson Junction (JJ) is a junction between two superconductors separated by a thin insulating layer. These capacitances are operated under vacuum (also referred to as vacuum capacitors) to avoid dielectric losses. The primary reason that these types of qubits are operated under vacuum is because of the extremely low temperatures required to achieve the ground state of the qubit (less than 0.05 K). Vacuum capacitors utilize flat metal plates located on a flat surface of a substrate. In this configuration, due to the higher dielectric constant of substrate, much of the electric field energy is concentrated in the material of the substrate causing losses. Moreover, in this configuration, the electric field is not confined and can influence negatively other parts of the circuit.

The present invention is directed towards a design for vacuum capacitor that would allow to minimize the amount electric field energy in the substrate and maximize the amount in vacuum, and at the same time confine the electric field as much as possible. The present invention is directed towards formation of a Qubit having a vacuum capacitor that minimizes the electric field absorption of substrate. The present invention exploits the lattice planes of the substrate to form an angled trench where metal plates of the capacitor are located on angled sidewalls of the trench. For example, a substrate that is comprised of (100)-oriented substrate can be exploited by utilizing an anisotropic wet etchant to form a trench in the substrate. When the wet etch terminates on (111) planes, this generates angled surfaces, which can be used as foundation for the capacitor plates. The angled surfaces are angled in the range of about 40 to 70 degrees, as measured from the top surface or boundary of the air gap to the angled surface. This geometry naturally confines the electric field and reduces the amount of electric field energy in the substate. Additionally, an air gap is formed beneath the capacitor plates to extend the vacuum beneath the capacitor plates, to further reduce the amount of the electrical field absorbed by the substrate.

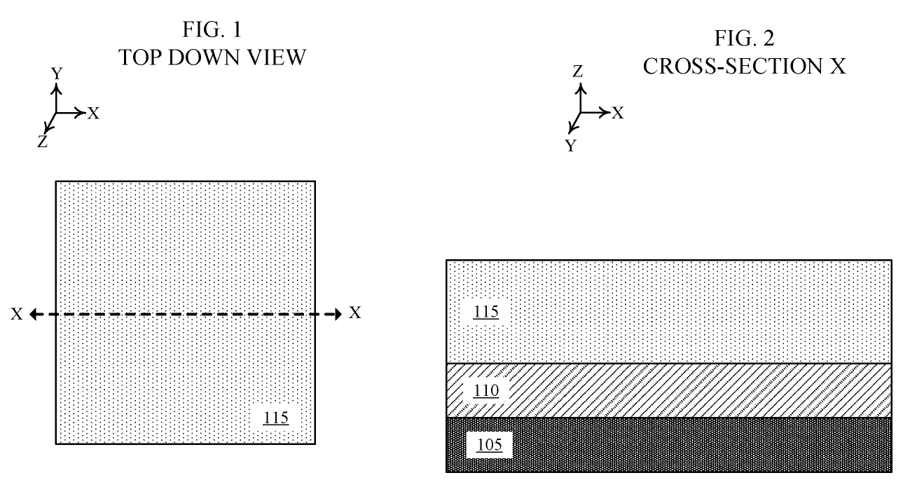

FIG. 1 illustrates a top-down view of Qubit, in accordance with the embodiment of the present invention. FIG. 2 illustrates cross-section X which extends horizontally through the Qubit.

Referring now to FIGS. 1 and 2 illustrate the processing stage after the formation of initial layers for the Qubit. FIG. 2 illustrates cross-section X that shows the first substrate 105, sacrificial layer 110, and the second substrate 115.

The first substrate 105 and the second substrate 115 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the first substrate 105 and the second substrate 115. In some embodiments, first substrate 105 and the second substrate 115 includes both semiconductor materials and dielectric materials. The semiconductor first substrate 105 and the second substrate 115 may also comprise an organic semiconductor or a layered semiconductor such as, for example, Si/SiGe, a silicon-on-insulator or a SiGe-on-insulator. A portion or the entire semiconductor first substrate 105 and the second substrate 115 may also be comprised of an amorphous, polycrystalline, or monocrystalline. The semiconductor first substrate 105 and the second substrate 115 may be doped, undoped or contain doped regions and undoped regions therein. The second substrate 115 can be comprised of a substrate that has (111) lattice orientation. In this embodiment, the second substrate 115 also possesses a (001) orientation (i.e.: their 001 planes lie parallel to the top second substrate 115 surface). In this orientation, the orientation of the 111 planes is angled with respect to (001). The sacrificial layer 110 is sandwiched between the first substrate 105 and the second substrate 115. The sacrificial layer 110 can have a thickness in the range of about 0.1 to 200 microns, preferably in the range of about 1 to 50 microns.

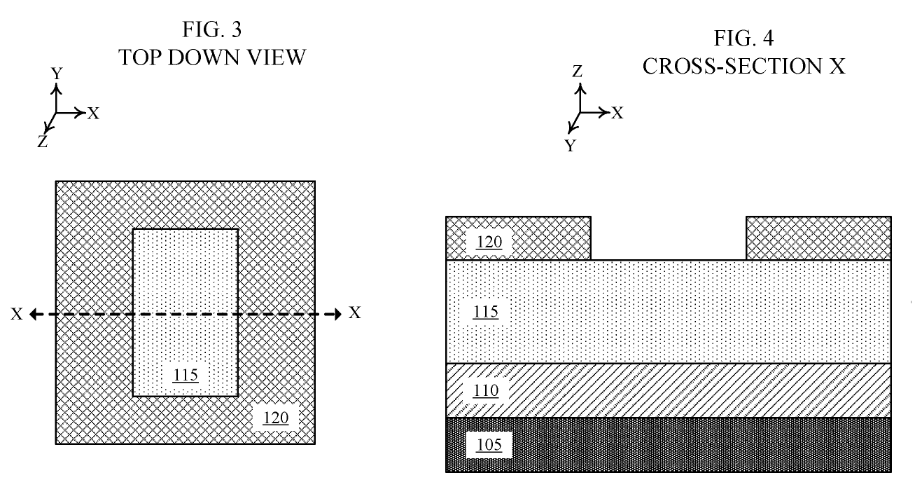

FIGS. 3 and 4 illustrate the processing stage after formation and development of a lithography layer 120. Lithography layer 120 is formed on top of the second substrate 115. The lithography layer 120 can be spun on, sputtered on, or formed by another means. The lithography layer 120 is pattern or develop to portions of the second substrate 115. FIG. 3 illustrates the portion of the lithography layer 120 that was removed to expose a portion of the second substrate 115.

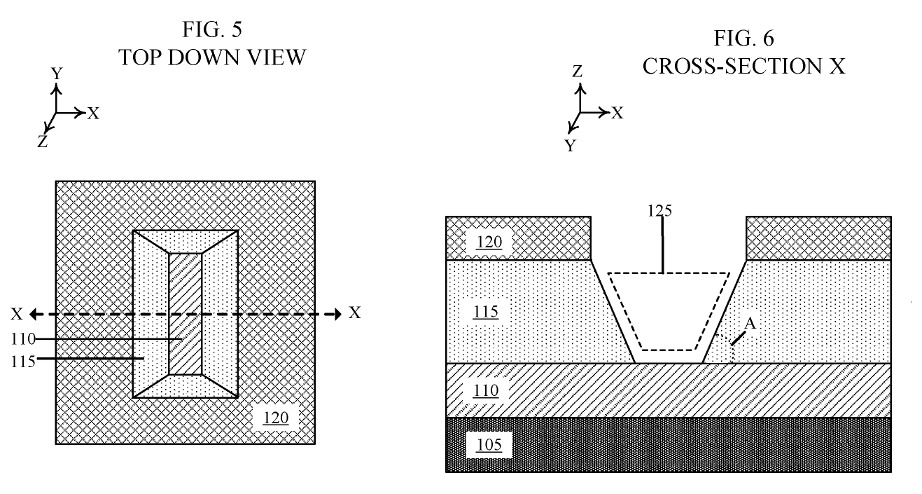

FIGS. 5 and 6 illustrate the processing stage after formation of the first trench 125. A first trench 125 is formed in the second substrate 115 in the area not covered by the lithography layer 120. Anisotropic etching process, for example, TMAH or KOH, is used to form the first trench 125. The anisotropic etching process is able to take advantage of the lattice orientation of the second substrate 115 to form angled sidewalls. The sacrificial layer 110 forms the bottom boundary or bottom surface of the first trench 125. Angled sidewalls of the second substrate 115 form the sidewalls or side boundaries of the first trench 125. The acute angle A of the sidewalls or side boundary of the trench is in the range of about 40 to 70 degrees, as measured from the top surface of the sacrificial layer 110 to the angled sidewall of the second substrate 115. The lattice orientation of the second substrate 115 and the anisotropic etching process will determine angle A of the angle sidewall or side boundary of first trench 125.

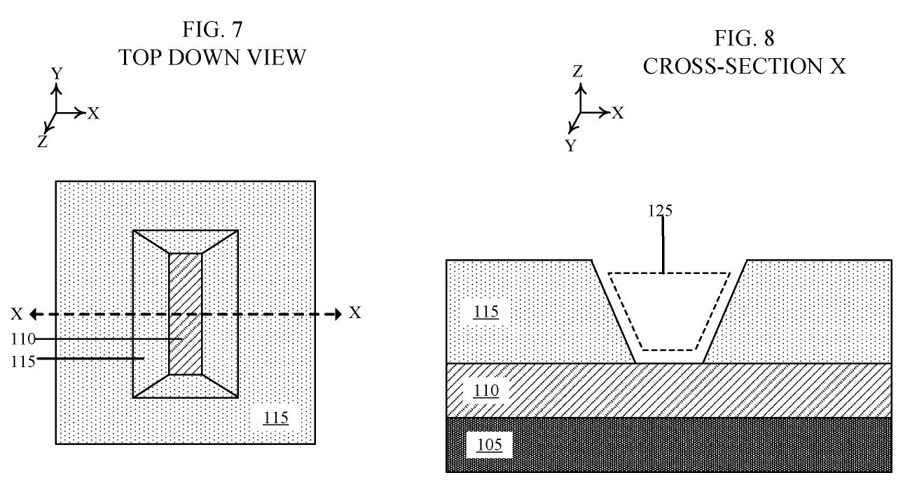

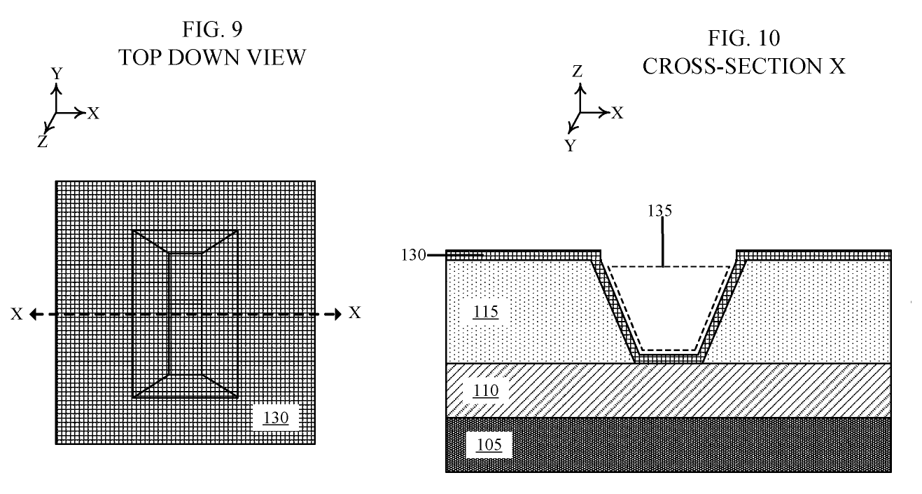

FIGS. 7 and 8 illustrate the processing stage after removal of the lithography layer 120. Lithography layer 120 is removed to expose the second substrate 115. FIGS. 9 and 10 illustrate the processing stage after formation of a metal layer 130. A metal layer 130 is formed on top of the exposed surface of the second substrate 115 and along the boundaries of the first trench 125. The first trench 125 will now be referred to as the lined trench 135 since the metal layer 130 is formed along the side boundaries/sidewalls and the bottom boundary of the first trench 125. This means that the metal layer 130 is formed on the exposed surface of the sacrificial layer 110 and along the angled sidewalls of the second substrate 115. The metal layer 130 is comprised of an elemental or compound superconducting material. For example, the metal layer 130 can be comprised of a material selected from a group consisting of niobium, tantalum, vanadium, rhenium, tin, aluminum, titanium, niobium nitride and titanium nitride.

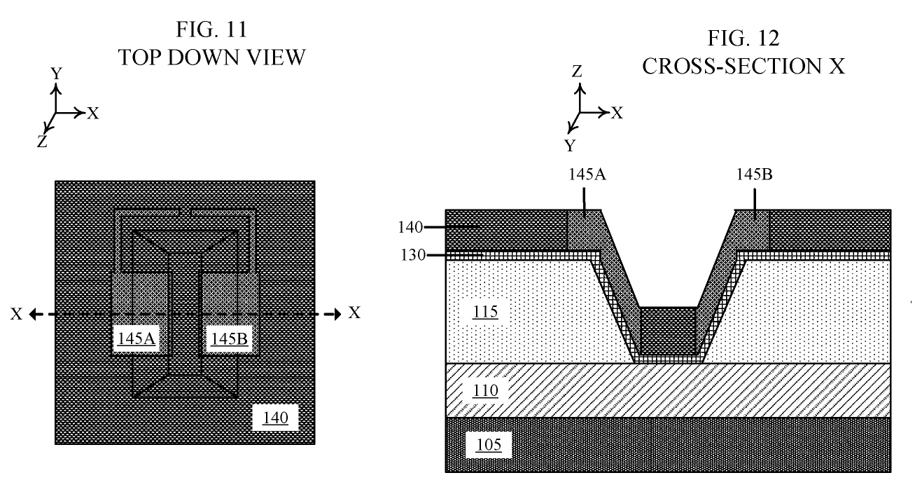

FIGS. 11 and 12 illustrate the processing stage after formation and exposure of a second lithography layer 140. A second lithography layer 140 is formed on top of the metal layer 130. An exposure process is utilized to form a pattern in the second lithography layer 140. The exposed pattern includes at least a first component 145A and a second component 145B. The first component 145A and the second component 145B will be utilized for the formation of the first and second capacitor plates from metal layer 130, which will be described in further detail below.

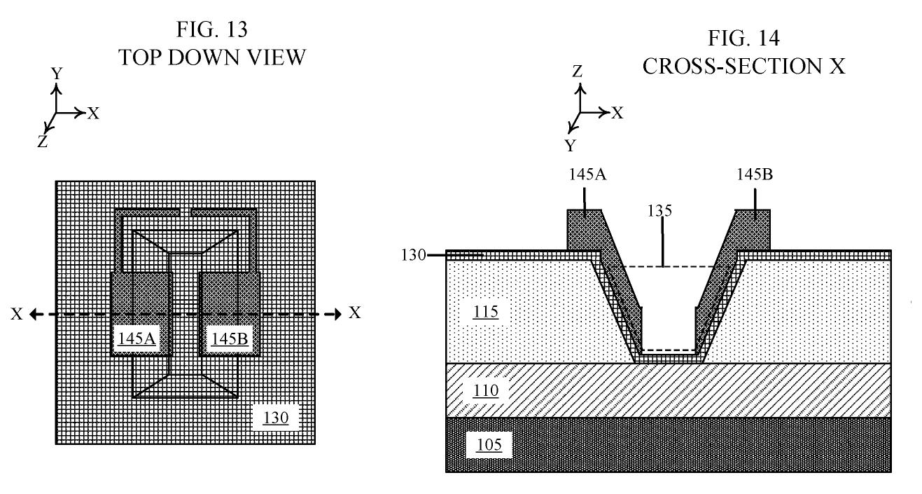

FIGS. 13 and 14 illustrate the processing stage after removal of the non-exposed portions of the second lithography layer 140. Most of the second lithography layer 140 is removed or stripped to expose portions of the underlying metal layer 130. The exposed pattern that includes at least a first component 145A and a second component 145B is not stripped or removed. The first component 145A and a second component 145B remains covering portions of the metal layer 130. The first component 145A and a second component 145B extend into the lined trench 135. Furthermore, the first component 145A and the second component 145B extend over portions of the metal layer 130 and include arms or branches that extend over flat horizontal sections of the metal layer 130 as illustrated in FIGS. 13 and 14.

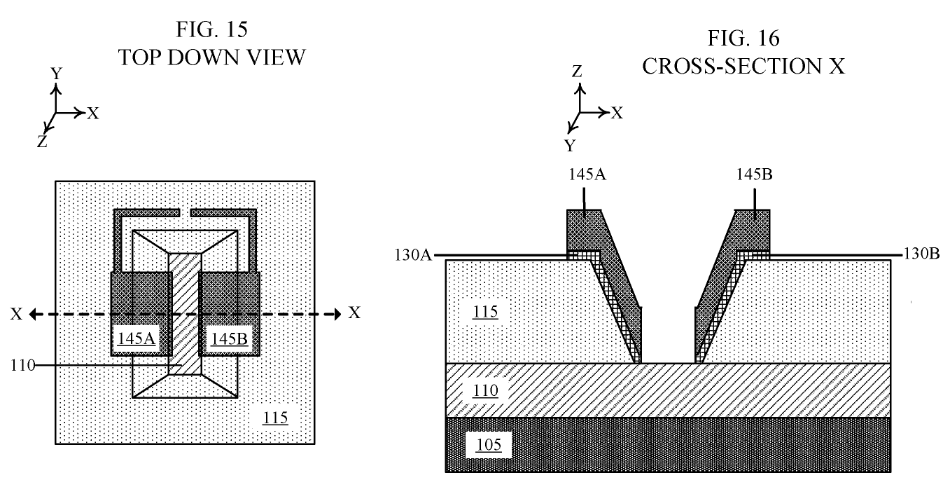

FIGS. 15 and 16 illustrate the processing stage after etching of the metal layer 130. The metal layer 130 is etched by, for example, reactive ion etching (RIE) or wet etching, to remove the portions of the metal layer 130 not covered by the first component 145A and the second component 145B. The remaining portions of the metal layer 130 will now be referred to as the first capacitor plate 130A and the second capacitor plate 130B. The first capacitor plate 130A and the second capacitor plate 130B extend along the sidewalls of the lined trench 135 and along the top surface of the second substrate 115 as illustrated in FIGS. 15 and 16. Lined trench 135 will now be referred to as the capacitor trench 150.

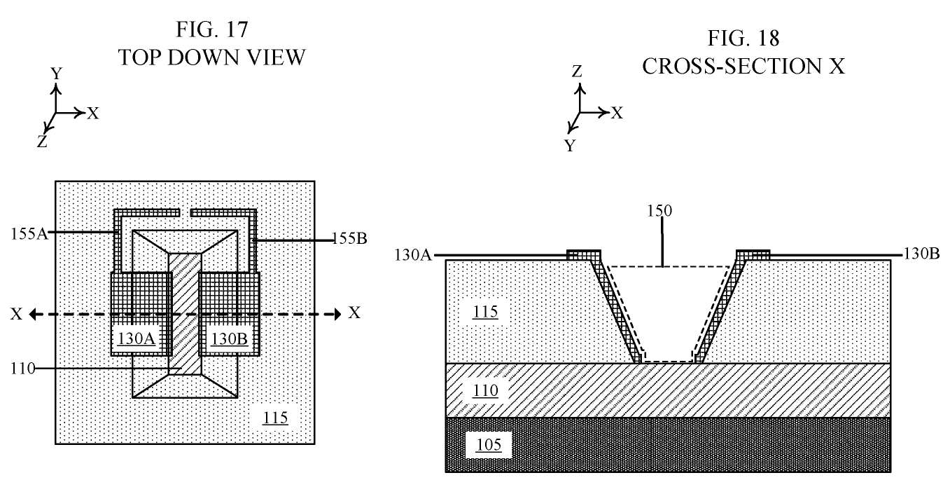

FIGS. 17 and 18 illustrate the processing stage after removal of the first component 145A and the second component 145B. The first component 145A and the second component 145B are removed to expose the first capacitor plate 130A and the second capacitor plate 130B. The first capacitor plate 130A includes a first connector 155A or first branch arm and the second capacitor plate 130B includes a second connector 155B or a second branch arm. Capacitor trench 150 has side wall boundaries comprised of the second substrate 115, the first capacitor plate 130A, and the second capacitor plate 130B. The bottom boundary of the capacitor trench 150 is formed by the sacrificial layer 110.

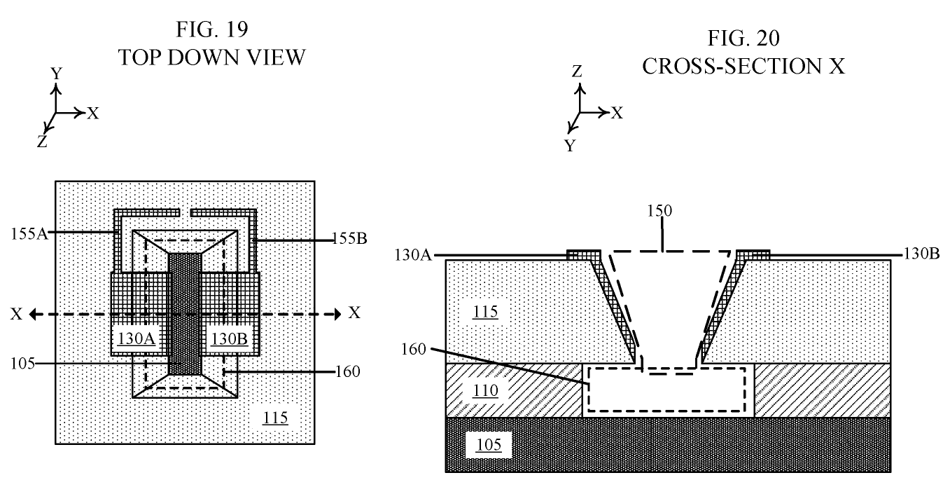

FIGS. 19 and 20 illustrate the processing stage after formation of the air gap 160. An etching process, for example, a wet etch is utilized to remove portions of the sacrificial layer 110 to form air gap 160. The etching process first removes the sacrificial layer 110 that is acting as the bottom boundary of the capacitor trench 150, and then laterally etches the sacrificial layer 110 to extend the air gap 160 under the second substrate 115. Air gap 160 extends under the first and second capacitor plates 130A, 130B and under portions of the second substrate 115 where the capacitor plates 130A, and 130B are not located, see for example, FIG. 19 where dash box represents the air gap 160. Air gap 160 is connected to capacitor trench 150, thus forming a combined opening.

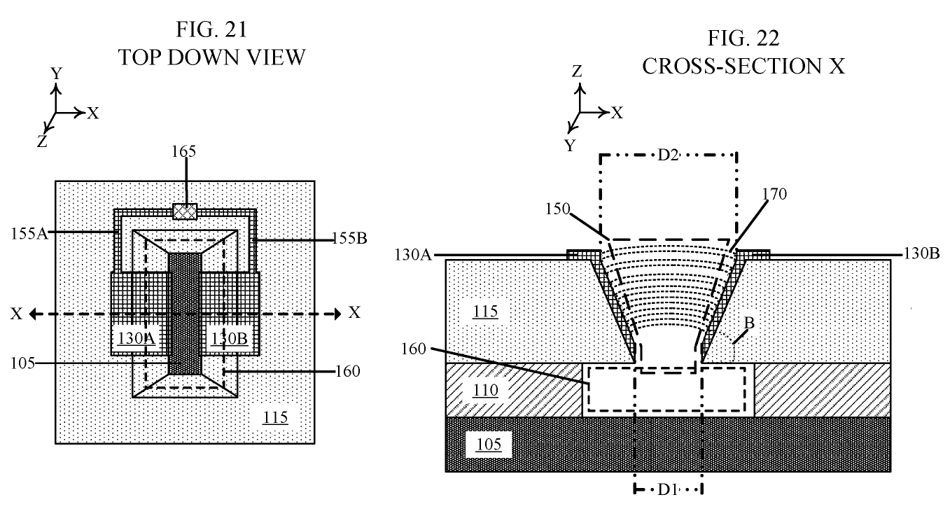

FIGS. 21 and 22 illustrate the processing stage after the formation of Josephson Junction 165. A Josephson Junction (JJ) 165 is formed between the first connector 155A and the second connector 155B. The first capacitor plate 130A and the second capacitor plate 130B have an angled surface that extends in parallel to the angled surface of the second substrate 115. The acute angle B of the sidewalls or side boundary of the trench is in the range of about 40 to 70 degrees, as measured from the bottom surface of the second substrate 115 to the angled sidewall of the capacitor plate 130A, 130B. Acute angle B is based on the lattice orientation or crystalline structure of the second substrate 115. The first capacitor plate 130A is located on the first side of the capacitor trench 150 and the second capacitor plate 130B is located on a second side of the capacitor trench 150. The first side is opposite the second side, such that, a top surface of the first capacitor plate 130A is angled towards a top surface of the second capacitor plate 130B and the top surface of the second capacitor plate 130B is angled towards the top surface of the first capacitor plate 130A. The distance varies between the first capacitor plate 130A and the second capacitor plate 130B as they extend along the angled sidewalls of the second substrate 115 or angled boundary of the capacitor trench 150. Capacitor trench 150 is angle such the first capacitor plate 130A and the second capacitor plate 130 are spaced apart from each other by a first distance D1 (this measurement is taken at the bottom of capacitor trench 150 closes to the air gap 160). The capacitor trench 150 is angle such the first capacitor plate 130A and the second capacitor plate 130 are spaced apart from each other by a second distance D2 (this measurement is taken at the top of capacitor trench 150 farthest from the air gap 160). The first distance D1 is smaller than the second distance D2. The second distance D2 between the first capacitor plate 130A and the second capacitor plate 130B is largest at the highest elevation of the first capacitor plate 130A and the second capacitor plate 130B. The first distance D1 between the first capacitor plate130A and the second capacitor plate130B is smallest at the lowest elevation (e.g., closest to the air gap 160) of the first capacitor plate 130A and the second capacitor plate 130B. The Qubit is formed from the JJ 165, the first capacitor plate 130A, and the second capacitor plate 130B. One or more metallization features (not shown) are used to raise the qubit to its excited state as well as perform readout of its state. Superconducting qubits are excited through capacitive or inducting coupling, rather than a direct, galvanic connection to the incoming signal in order to reduce leakage and environmental noise. The qubit is operated under vacuum the capacitor trench 150 will become the vacuum trench 150. The vacuum is extended to the air gap 160 (because air gap 160 is connected to the vacuum trench 150) allowing for the vacuum to extend beneath the first and second capacitor plates 130A, 130B. When power is applied to the qubit an electric field 170 is generated between the first capacitor plate 130A and the second capacitor plate 130B. Then angled capacitor plates 130A, 130 and the vacuum space (e.g., the capacitor trench 150 and the air gap) reduces the amount of the electric field 170 absorbed by the second substrate 115.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A structure comprising:
a first capacitor plate located on a first surface of a substrate; and
a second capacitor plate located on a second surface of the substrate, wherein a top surface of the first capacitor plate is angled towards a top surface of the second capacitor plate.

2. The structure of claim 1, wherein the angle of the first and second capacitor plate is based on the crystalline structure of the substrate.

3. The structure of claim 1, wherein a distance between the first capacitor plate and the second capacitor plate varies.

4. The structure of claim 3, wherein the distance between the first capacitor plate and the second capacitor plate is largest at the highest elevation of the first capacitor plate and the second capacitor plate.

5. The structure of claim 4, wherein the distance between the first capacitor plate and the second capacitor plate is smallest at the lowest elevation of the first capacitor plate and the second capacitor plate.

6. The structure of claim 5, further comprising:
a vacuum trench that extends between the first capacitor plate and the second capacitor plate.

7. The structure of claim 1, wherein the first capacitor plate includes a portion that extends along a flat top surface of the substrate.

8. The structure of claim 7, wherein the second capacitor plate includes a portion that extends along the flat top surface of the substrate.

9. A structure comprising:
a first capacitor plate located on a first surface of a substrate;
a second capacitor plate located on a second surface of the substrate, wherein a top surface of the first capacitor plate is angled towards a top surface of the second capacitor plate; and
an air gap located beneath the first capacitor plate and the second capacitor plate.

10. The structure of claim 9, wherein the air gap extends beneath the substrate where the first capacitor plate and the second capacitor plate are not located.

11. The structure of claim 10, further comprising:
a vacuum trench that extends between the first capacitor plate and the second capacitor plate.

12. The structure of claim 11, wherein the air gap is connected to the vacuum trench.

13. The structure of claim 12, wherein the angle of the first and second capacitor plate is based on the crystalline structure of the substrate.

14. The structure of claim 13, wherein a distance between the first capacitor plate and the second capacitor plate varies.

15. The structure of claim 14, wherein the air gap extends beneath the substrate where the first capacitor plate and the second capacitor plate are not located.

16. A structure comprising:
a first capacitor plate located on a first surface of a substrate, wherein the first capacitor plate includes a first branch arm that extends along a flat surface of the substrate;
a second capacitor plate located on a second surface of the substrate, wherein the second capacitor plate includes a second branch arm that extends along the flat surface of the substrate, wherein a top surface of the first capacitor plate is angled towards a top surface of the second capacitor plate; and
a Josephson Junction is located between the first branch arm and the second branch arm.

17. The structure of claim 16, further comprising:
an air gap located beneath the first capacitor plate and the second capacitor plate.

18. The structure of claim 17, wherein the air gap extends beneath the substrate where the first capacitor plate and the second capacitor plate are not located.

19. The structure of claim 18, further comprising:
a vacuum trench that extends between the first capacitor plate and the second capacitor plate, and wherein the air gap is connected to the vacuum trench.

20. The structure of claim 16, wherein the angle of the first and second capacitor plate is based on the crystalline structure of the substrate.
